(19) United States
(12) Patent Application Publication
(10) Pub. No.: US 2018/0157203 A1
(43) Pub. Date: Jun. 7, 2018

(54) IMAGE FORMING APPARATUS

(71) Applicant: CANON KABUSHIKI KAISHA, Tokyo (JP)

(72) Inventors: Hideki Mori, Toride-shi (JP); Jun Shirayanagi, Ushiku-shi (JP); Dai Kanai, Abiko-shi (JP); Teppei Nagata, Abiko-shi (JP); Kotaro Torikata, Chigasaki-shi (JP); Makoto Matsuo, Kashiwa-shi (JP); Kenta Koyama, Tokyo (JP); Hideki Takaoka, Kawasaki-shi (JP); Masatoshi Lin, Kawasaki-shi (JP)

(21) Appl. No.: 15/825,632

(22) Filed: Nov. 29, 2017

(30) Foreign Application Priority Data
Dec. 5, 2016 (JP) 2016-236256
Mar. 17, 2017 (JP) 2017-053504

(51) Int. Cl. G03G 15/00; G01N 21/88; G03F 1/84

(52) U.S. Cl. CPC G03G 15/5016; G03F 1/84; G01N 21/8806

(57) ABSTRACT

An image forming apparatus includes a main assembly including a feeding portion configured to feed a sheet and an image forming portion configured to form an image on the fed sheet, an openable cover provided on a side surface of the main assembly and openable for exposing a component part in the main assembly by opening a space above the component part with respect to a vertical direction, and a projecting portion provided above the openable cover with respect to the vertical direction and capable of projecting light toward the component part when the openable cover is opened.

### FIELD OF THE INVENTION AND RELATED ART

The present invention relates to an image forming apparatus for displaying operation guidance for notifying an operator of an operation procedure such as clearance of paper jam or exchange of consumables.

Conventionally, in the image forming apparatus, such as a copying machine, of an electrophotographic type, in some cases, there is a need for an operator to perform operations such as the clearance of paper jam (jamming), the exchange of the consumables and component parts, supply of a developer, supply of sheets, and the like. For that reason, in the image forming apparatus, on a screen of an operating portion, operation guidance for notifying the operator of pieces of information on an operation procedure, a state of the image forming apparatus and matters to be attended to has been displayed.

However, in some cases, a screen provided at an operating portion is small and the screen of the operation portion and a portion-to-be-operated are away from each other, and therefore the operator does not readily recognize the operation procedure and the portion-to-be-operated.

Therefore, Japanese Laid-Open Patent Application (JP-A) 2010-128120 has proposed that a plurality of screens and provided in an image forming apparatus and operation guidance is displayed from a projector onto either one of screens depending on the portion-to-be-operated.

However, the image forming apparatus disclosed in JP-A 2010-128120, there is a need to provide the plurality of screens. Further, in order to carry out proper display on the plurality of screens, there is a need to provide a means for changing a direction of the projecting means and a means for adjusting magnification, and therefore, the image forming apparatus is increased in size and is complicated, with the result that the image forming apparatus is expensive. Further, depending on a place of the screens and an operation position of the operator, the operation guidance projected from the projector is blocked by the portion-to-be-operated and the operator, so that the operator does not readily recognize the operation guidance.

### SUMMARY OF THE INVENTION

A principal object of the present invention is to provide an image forming apparatus capable of properly project operation guidance onto a plurality of projection objects with a simple constitution.

According to an aspect of the present invention, there is provided an image forming apparatus comprising: a main assembly including a feeding portion configured to feed a sheet and an image forming portion configured to form an image on the fed sheet; an openable cover provided on a side surface of the main assembly and openable for exposing a component part in the main assembly by opening a space above the component part with respect to a vertical direction; and a projecting portion provided above the openable cover with respect to the vertical direction and capable of projecting light toward the component part when the openable cover is opened.

Further features of the present invention will become apparent from the following description of exemplary embodiments with reference to the attached drawings.

### BRIEF DESCRIPTION OF THE DRAWINGS

FIG. 1 is a sectional view of an image forming apparatus in Embodiment 1.

FIG. 2 is a sectional view of a process unit.

Parts (a) and (b) of FIG. 3 are perspective views of the image forming apparatus.

Part (a) of FIG. 4 is a side view of the image forming apparatus and parts (b) and (c) of FIG. 4 are top plan views of the image forming apparatus.

Part (a) of FIG. 5 is a perspective view of the image forming apparatus, and part (b) of FIG. 5 is a top plan view of the image forming apparatus.

Part (a) of FIG. 6 is a perspective view of an image forming apparatus in Embodiment 2, and part (b) of FIG. 6 is a side view of the image forming apparatus.

Part (a) of FIG. 7 is a front view of an image forming apparatus in Embodiment 4, and part (b) of FIG. 7 is a side view of the image forming apparatus.

FIG. 8 is a perspective view of an image forming apparatus in Embodiment 4.

FIG. 9 is a perspective view of the image forming apparatus in a state in which a manual feeding tray is open.

FIG. 10 is a sectional view of the image forming apparatus in a state in which a right(-hand) door is open.

FIG. 11 is a perspective view of the image forming apparatus in the state in which the right door is open.

Parts (a) and (b) of FIG. 12 are perspective views for illustrating an example of operation guidance in the state in which the right door is open.

Parts (a) and (b) of FIG. 13 are perspective views showing a sheet sensor.

Parts (a) and (b) of FIG. 14 are perspective views showing an image forming apparatus in Embodiment 5.

Part (a) of FIG. 15 is a top plan view of an image forming apparatus in Embodiment 6, and parts (b) and (c) of FIG. 15 are side views showing the image forming apparatus.

### DESCRIPTION OF EMBODIMENTS

An image forming apparatus according to the present invention will be specifically described with reference to the drawings.

### Embodiment 1

### 1. General Structure of Image Forming Apparatus

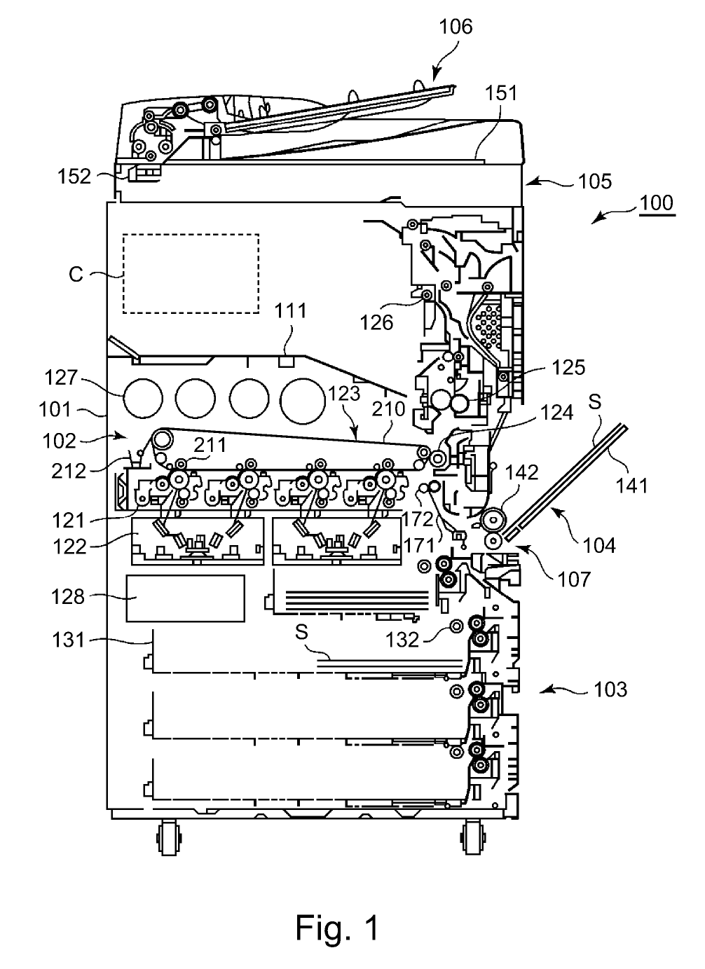

FIG. 1 is a sectional view of an image forming apparatus 100 in this embodiment. The image forming apparatus 100 in this embodiment is a multi-function machine which is capable of forming a full-color image by using an electrophotographic type and which has functions of a copying machine, a printer and a facsimile machine.

Here, as regards the image forming apparatus 100, a front side of the surface of the drawing sheet of FIG. 1 is a “front surface (or front)”, and a rear side of the surface of the drawing sheet of FIG. 1 is a “rear (surface) (or back (surface))”. A depth direction (front-rear direction) connecting the front side and the rear side of the image forming apparatus 100 is substantially parallel to a rotational axis direction of a photosensitive drum 203 described later. Further, a left-right direction as to the image forming apparatus 100 is a left-right direction in the case where the image forming apparatus 100 is seen from the front side. Further, an up-down direction as to the image forming apparatus 100 refers to an up-down direction, but does not mean only just above and just below, and includes an upper side and a lower side with respect to a horizontal plane passing through a noted element or position. These directions refer to directions in a state in which the image forming apparatus 100 is installed so that the image forming apparatus 100 can be normally used.

The image forming apparatus 100 includes an apparatus main assembly 101. In the apparatus main assembly 101, an image forming portion 102, a sheet feeding device 103, a manual feeding portion 104, an original reading portion 105, a sheet feeding (conveying) portion 107, a controller C and the like are provided.

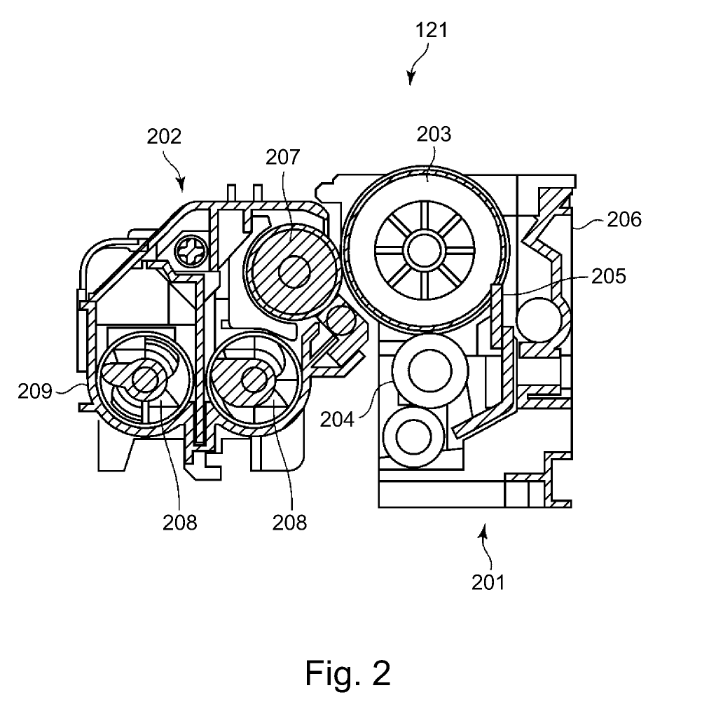

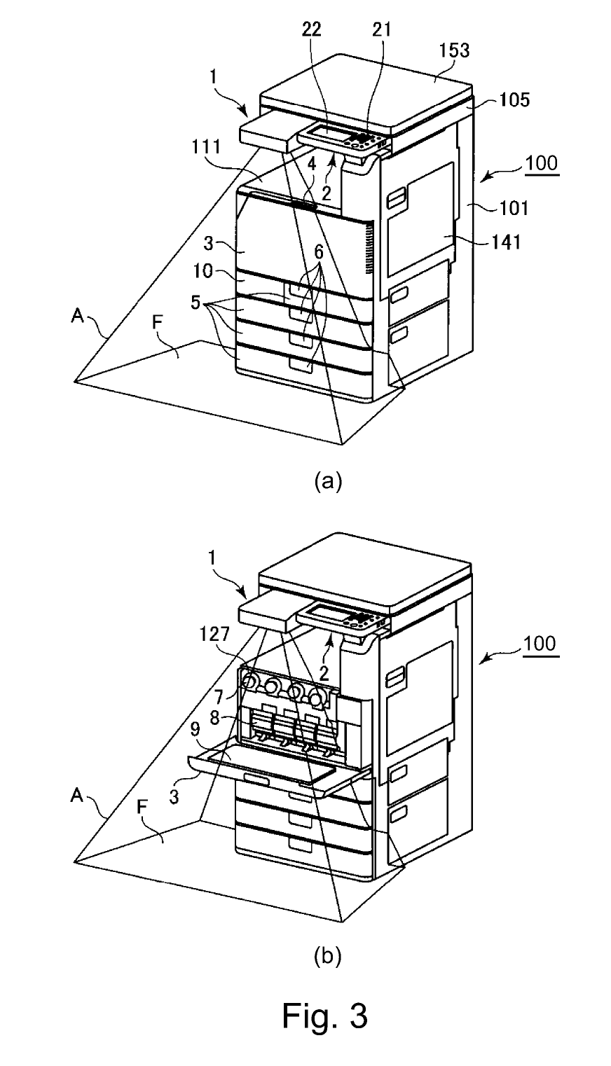

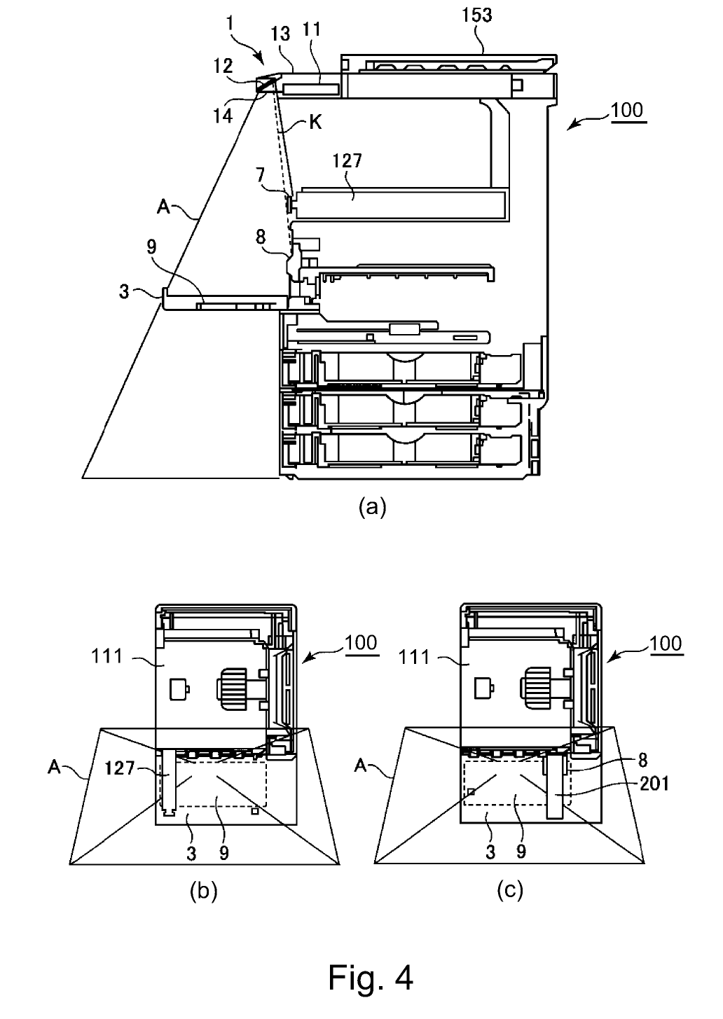

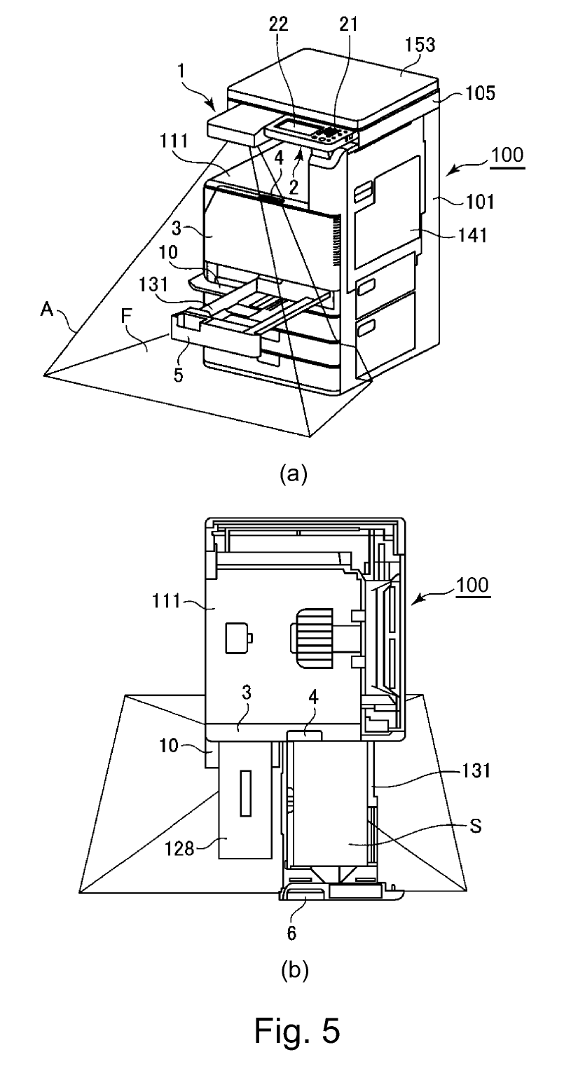

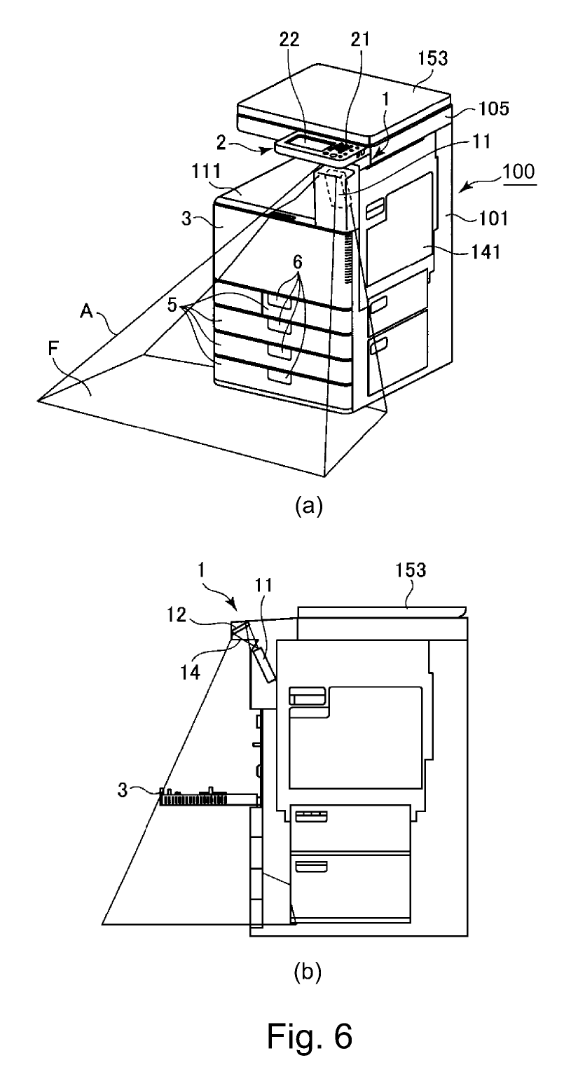

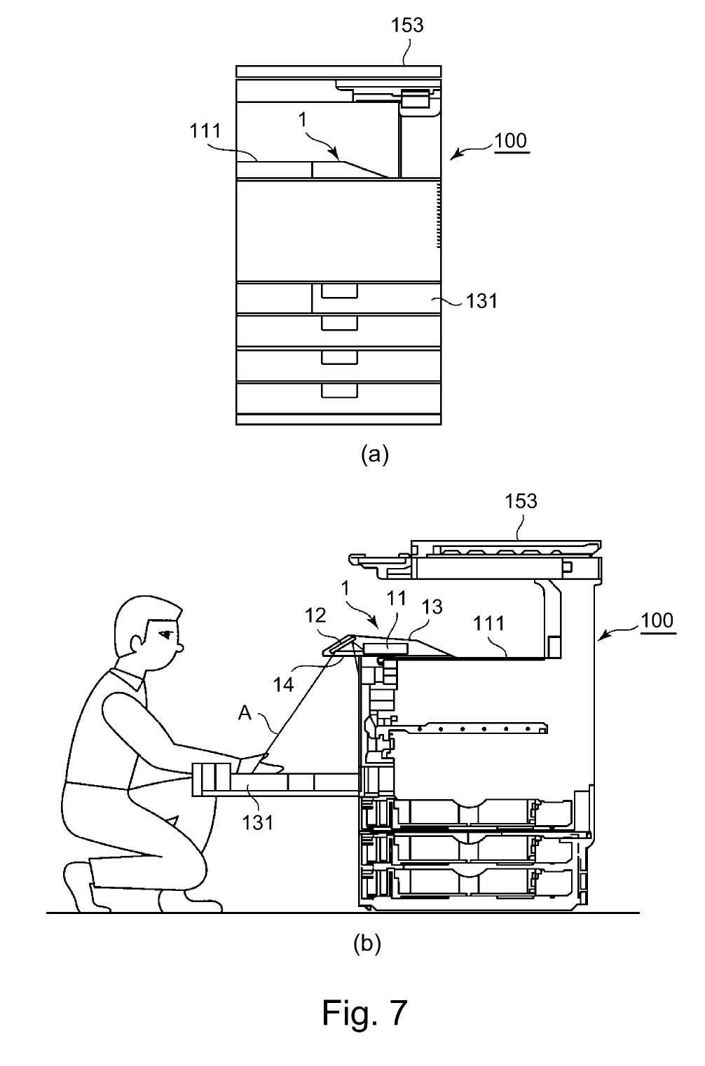

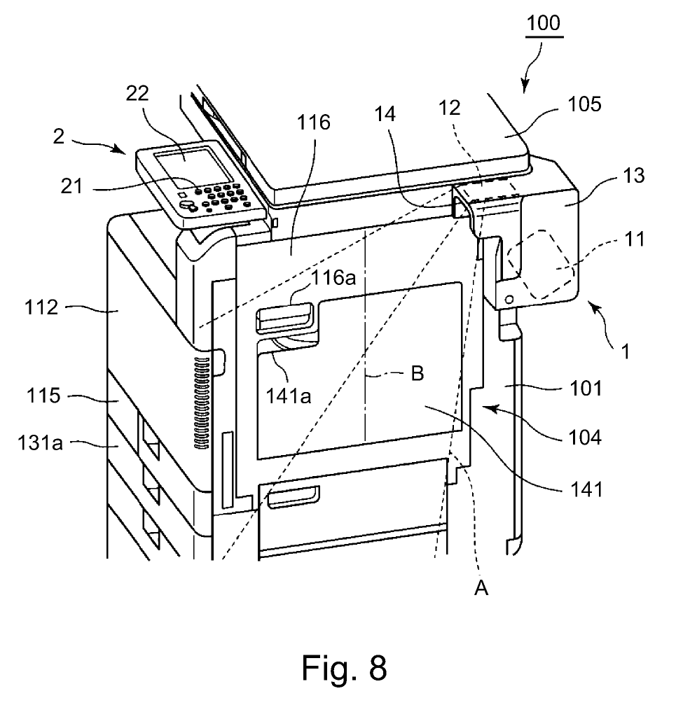

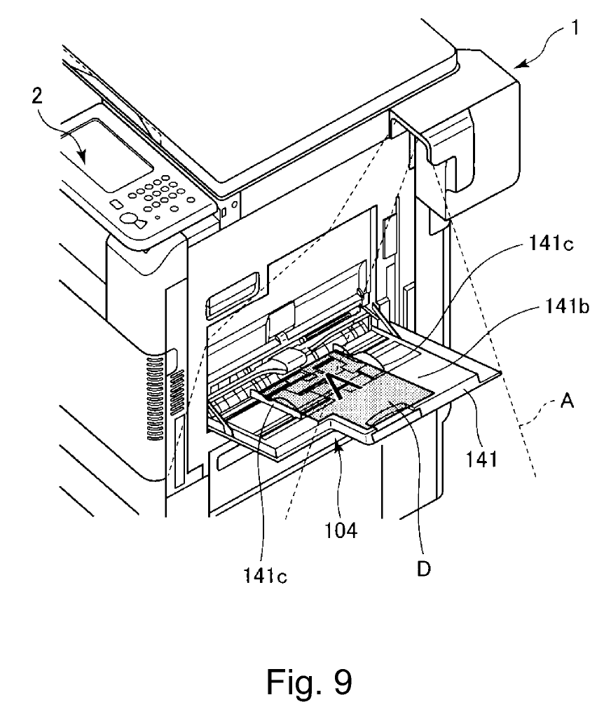

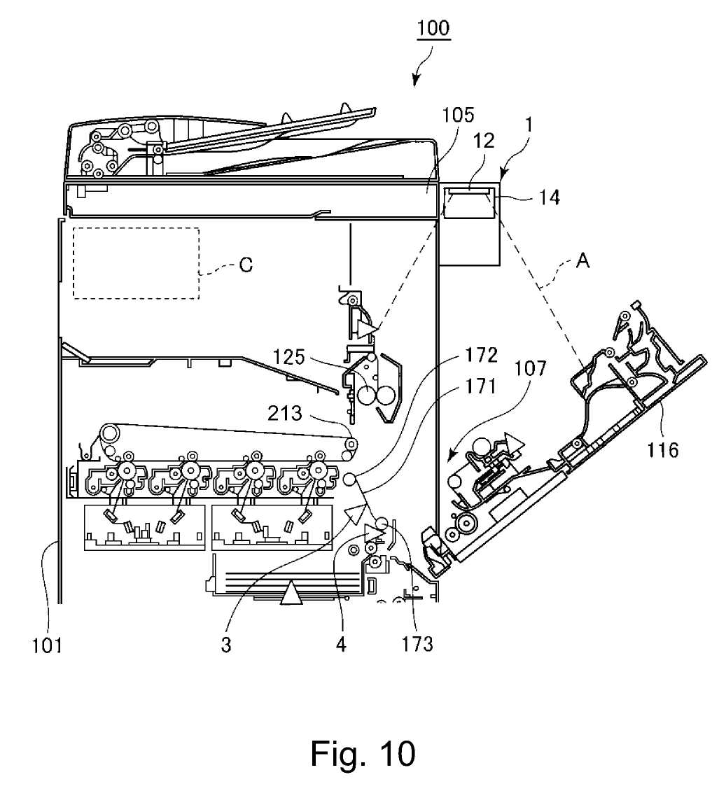

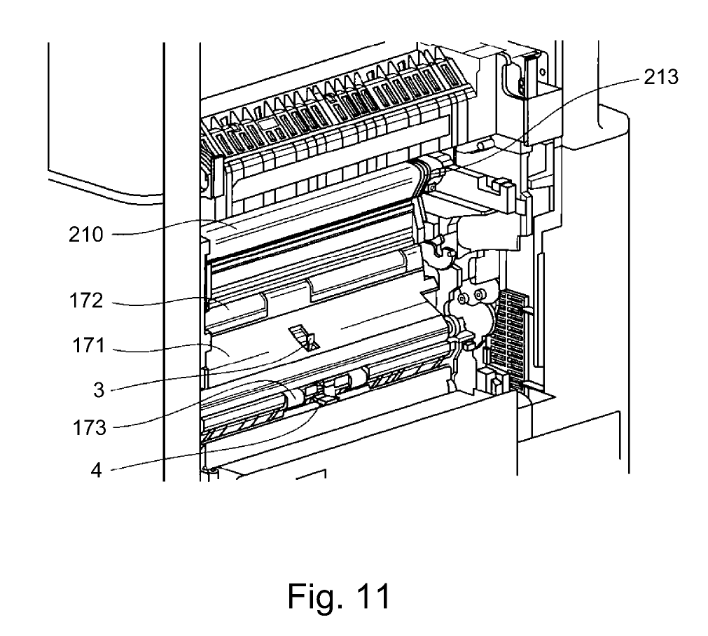

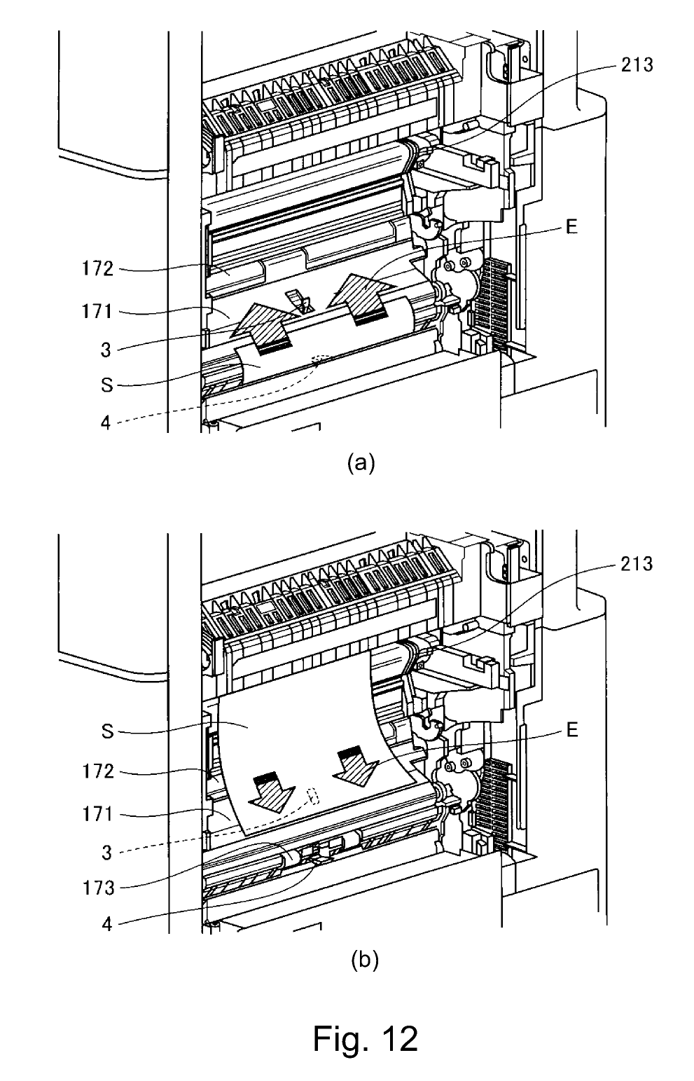

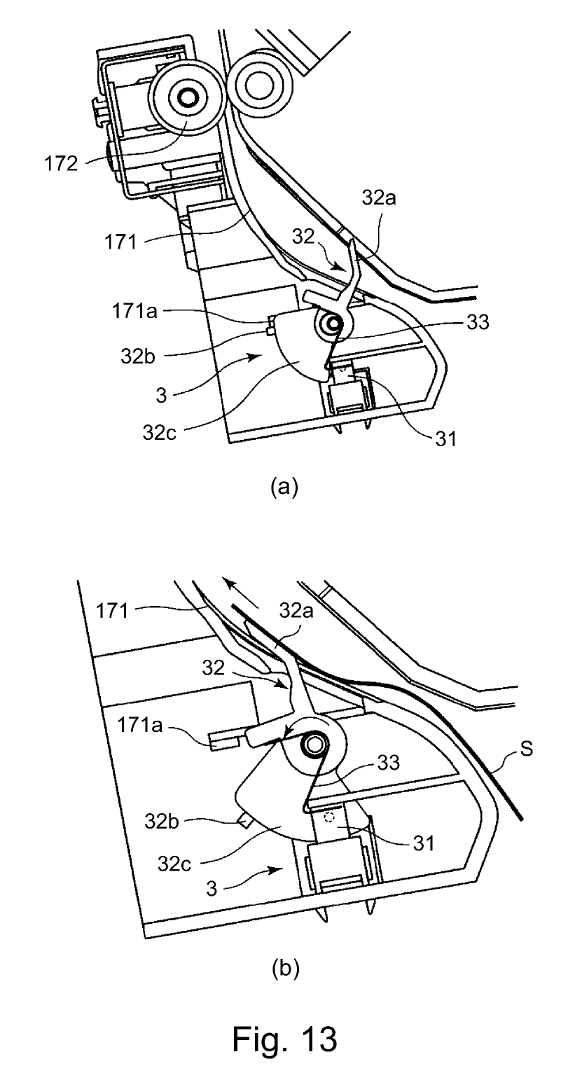

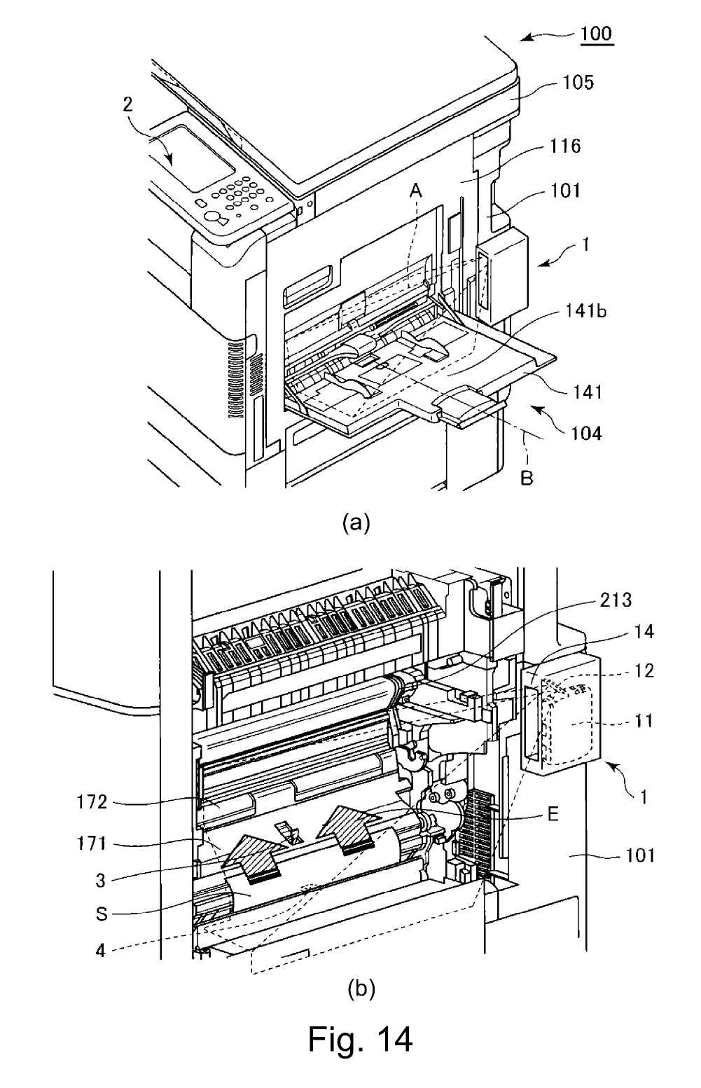

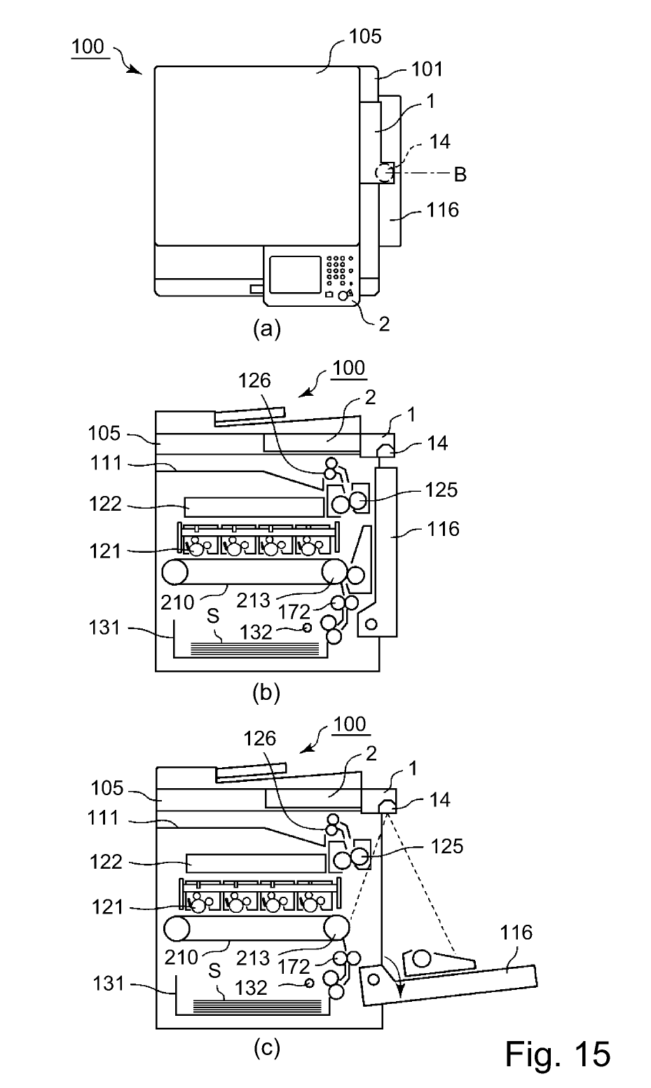

The image forming portion 102 includes a process unit 121, a laser scanner unit 122, an intermediary transfer unit 123, a secondary transfer roller 124, a fixing device 125, a discharging roller 126, a toner cartridge 127, a collecting container 128 and the like. In this embodiment, four process units 121 are provided and arranged substantially in a horizontal direction. These four process units 121 have substantially the same constitution except that colors of toners used for image formation are different from each other. FIG. 2 is a sectional view specifically showing a single process unit 121 as a representative.

The process unit 121 includes a drum unit 201 and a developing unit 202. The drum unit 201 is constituted by a photosensitive drum 203 which is a drum-shaped (cylindrical) photosensitive member (electrophotographic photosensitive member), a charging roller 204, a drum cleaner 205, and a drum unit container 206 for supporting these members. The developing unit 202 is constituted by a developing roller 207, a feeding screw 208, and a developing unit container 209 for supporting these members and accommodating a developer. In this embodiment, the developing unit 202 uses, as the developer, a two-component developer containing toner (non-magnetic toner particles) and a carrier (magnetic carrier particles). The drum unit 201 and the developing unit 202 are individually detachably mountable to the apparatus main assembly 101 by being inserted into and pulled out from the apparatus main assembly 101. The intermediary transfer unit 123 is constituted by an intermediary transfer belt 210 stretched by a plurality of stretching rollers, primary transfer rollers 211 provided in an inner peripheral surface side of the intermediary transfer belt 210 so as to be disposed correspondingly to the respective photosensitive drums 203, and a belt cleaner 212 and the like. In this embodiment, correspondingly to the four process units 121, four toner cartridges 127 are provided and arranged substantially in the horizontal direction. In the toner cartridges 127, toners of yellow (Y), magenta (M), cyan (C) and black (K) are accommodated, respectively. The respective toner cartridges 127 are individually detachably mountable to the apparatus main assembly 101 by being inserted into and pulled out from the apparatus main assembly 101.

The sheet feeding device 103 is constituted by a plurality of sheet accommodating portions 131 as accommodating members for accommodating sheets (transfer materials, recording materials) S such as recording sheets, a feeding roller 132 for feeding the sheets S accommodated in the sheet accommodating portion 131, and the like. The sheet accommodating portion 131 is capable of being pulled out toward the front side of the apparatus main assembly 101.

The manual feeding portion 104 is constituted by a manual feeding tray 141 on which the sheets S are stacked, a manual feeding roller 142 for feeding (sending) the sheet(s) S stacked on the manual feeding tray 141, and the like. The manual feeding tray 141 is provided on a right-hand side surface of the apparatus main assembly 101 so as to be openable. In the case where the manual feeding portion 104 is used, the manual feeding tray 141 is opened and projected to a position where the sheets S are feedable, and the sheets S are stacked on the projected manual feeding tray 141.

The original reading portion 105 is constituted by a platen glass 151 as an original carriage, a reading device 152, and the like. The reading device 152 optically reads an original stacked (put) on the platen glass 151 and converts the read data into an electric signal. In FIG. 1, in order to permit continuous reading of a plurality of originals by the reading device 152, at an upper portion of the original reading portion 105, an automatic original (document) feeding device 106 is provided. In FIGS. 3 to 7, a state in which in place of the automatic original feeding device 106, a pressure plate 153 for pressing the original put on the platen glass 151 is mounted is shown.

The sheet feeding portion 107 is constituted by the surface feeding device 103, a sheet feeding path 171 along which the sheet S sent from the manual feeding portion 104, a registration roller pair 172 for carrying out correction of oblique movement of the sheet S and control of feeding timing of the sheet S, and the like.

The collecting container 128 is a container for collecting the toner discharged as waste from the image forming portion 102. The collecting container 128 is detachably mountable to the apparatus main assembly 101 by being inserted into and pulled out from the apparatus main assembly 101.

In this embodiment, operations of the respective portions of the image forming apparatus 100 is subjected to centralized correspond by the controller C provided in the apparatus main assembly 101.

### 2. Image Forming Operation

An image forming operation of the image forming apparatus 100 will be described by taking a copying operation as an example. When an image reading signal is outputted from the controller C to the image reading portion 105, an image of the original is read by the image reading portion 105, and image information is sent to the image forming portion 102. In the image forming portion 102, the surface of the photosensitive drum 203 electrically charged uniformly by the charging roller 204 is irradiated with laser light corresponding to the image information from the laser scanner unit 122, so that an electrostatic latent image (electrostatic image) is formed on the photosensitive drum 203. The electrostatic latent image formed on the photosensitive drum 203 is developed (visualized) by being supplied with the toner by the developing unit 202, so that a toner image is formed on the photosensitive drum 203. The toner image formed on the photosensitive drum 203 is primary-transferred, at a primary transfer portion where the intermediary transfer belt 210 and the photosensitive drum 203 is in contact with each other, onto the intermediary transfer belt 210 by the action of the primary transfer roller 211. For example, during full-color image formation, the toner images of yellow, magenta, cyan and black are successively primary-transferred superposedly from the respective photosensitive drums 203 onto the intermediary transfer belt 210.

On the other hand, when a sheet feeding signal is outputted from the controller C to the sheet feeding device 103, the sheet S is fed from the sheet accommodating portion 131 by the feeding roller 132. When the sheet feeding signal is outputted from the controller C to the manual feeding portion 104, the sheet S is sent from the manual feeding tray 141 by the manual feeding roller 142. Thereafter, the sheet S is conveyed along the sheet feeding path 171, and not only the oblique movement of the sheet S is corrected by the registration roller pair 172 but also the sheet S is timed to the toner images on the intermediary transfer belt 210, and then the sheet S is sent to a secondary transfer portion where the intermediary transfer belt 210 and a secondary transfer roller 124 are in contact with each other.

At the secondary transfer portion, the toner images formed on the intermediary transfer belt 210 are secondary-transferred onto the sheet S by the action of the secondary transfer roller 124. The sheet S on which the toner images are secondary-transferred is heated and pressed by the fixing device 125, so that the toner images are fixed (melt-fixed) on the sheet S. The sheet S on which the toner images are fixed is discharged and stacked by the discharging roller 126 on a discharge tray 111 as a stacking portion provided at an outer portion of the apparatus main assembly 101.

Further, toner (primary transfer residual toner) remaining on the photosensitive drum 203 after a primary transfer step is removed and collected from the photosensitive drum 203 by the drum cleaner 205. Further, toner (secondary transfer residual toner) remaining on the intermediary transfer belt 210 after a secondary transfer step is removed and collected from the intermediary transfer belt 210 by a belt cleaner 212. The toners collected by the drum cleaner 205 and the belt cleaner 212 are accommodated in a collecting container 128 through a collecting toner feeding path (not shown). Further, the image forming portion 102 is provided with a toner hopper (not shown) in which the toner supplied from the toner cartridge 127 is stored and from which the toner in an amount corresponding to an amount of the toner consumed by the development is supplied to the developing unit 202. When the toner in the toner hopper is consumed by the development, the toner is supplied from the toner cartridge 127 to the toner hopper.

### 3. Operating Portion

An operating portion 2, provided outside the apparatus main assembly 101, for inputting an instruction as the operation of the image forming portion 102 will be described. Parts (a) and (b) of FIG. 3 are perspective views of the image forming apparatus 100 of which a front surface, right side surface and an upper surface are shown, wherein part (a) of FIG. 3 shows a state in which a front door (front cover) 3 described later is closed, and part (b) of FIG. 3 shows a state in which the front door 3 is open. Incidentally, in this embodiment, in a state in which the openable front door 3 is closed and a pullable accommodating member is accommodated, in the case where the image forming apparatus 100 is seen from above, the image forming apparatus 100 has a substantially rectangular shape such that a front side surface and a rear side surface are substantially parallel to each other and that a left side surface and a right side surface are substantially parallel to each other.

In this embodiment, the image forming apparatus 100 includes, on the front side surface, particularly on the front side surface of the image reading portion 105, the operating portion 2 for permitting input of various settings such as a process condition of the sheet S, a start instruction of the image forming operation, and the like to the controller C. In this embodiment, the operating portion 2 is provided so as to project from the front side surface of the image reading portion 105 toward the front side. Further, in this embodiment, when the image forming apparatus 100 is seen from the front side, the operation portion 2 is provided in a right side more than a central portion with respect to a left-right direction.

The operating portion 2 is constituted by buttons (switches) 21 as input means for permitting input of instructions to the controller C, a display (liquid crystal screen) 22 as a display means for displaying information for an operator such as a user or a maintenance person. In this embodiment, the display 22 is constituted by a touch panel and also has a function of an input means. The operator operates, in general, the operating portion 2 from the front side of the image forming apparatus 100, so that the operator can input necessary items to the controller C and can cause the image forming apparatus 100 to start the image forming operation.

Further, the image forming apparatus 100 is configured so that the operator can perform maintenance (exchange) from the front side of the image forming apparatus 100 where the operator portion 2 is provided. That is, on the front side surface of the image forming apparatus 100, the front door 3 as a door member openable for exposing at least a part of the image forming portion 102 to the outside of the image forming apparatus 100 is provided. By operation a front door grip 4, the front door 3 can be opened by being rotated from above toward below about a rotational axis substantially parallel to the horizontal direction and can be closed by being rotated from below toward above about the rotational axis (horizontal direction hinge).

When the front door 3 is opened, end portions of the toner cartridges 127 in the front side and small doors 8 for exposing end portions of the process units 121 in the front side to an outside of the image forming apparatus 100 are exposed to the outside of the image forming apparatus 100. In this embodiment, four toner cartridges 127 and four small doors 8 are provided and arranged substantially in the horizontal direction correspondingly to four process units 121. Each of the toner cartridges 127 can be mounted into and demounted from the apparatus main assembly 101 by being inserted into and pulled out from the apparatus main assembly 101 in the front-rear direction by operating a cartridge grip 7 provided at the end portion thereof in the front side. Further, by opening the small door 8, the drum unit 201 and the developing unit 202 can be mounted into the demounted from the apparatus main assembly 101 by being individually inserted into and pulled out from the apparatus main assembly 101 in the front-rear direction. The small door 8 is opened by being rotated from above toward below about a rotational axis substantially parallel to the horizontal direction, and is closed by being rotated from below toward above about the rotational axis. In this embodiment, the small door 8 also functions as a lever as a portion-to-be-operated for changing the state of the drum unit 201 and the developing unit 202 between a detachably mountable state and a set state.

In the front side of the image forming apparatus 100, accommodating portion outer surfaces 5 which are front side-side surface of the sheet accommodating portions 131 are provided. In this embodiment, four accommodating portion outer surfaces 5 are disposed along an up-down direction, and a size of the uppermost accommodating portion outer surface 5 with respect to the left-right direction is smaller than those of other accommodating portion outer surfaces with respect to the left-right direction. Each of the sheet accommodating portions 131 is configured so as to be inserted into and pulled out from the apparatus main assembly 101 by operation an accommodating portion grip 6 provided on the accommodating portion outer surface 5, so that the sheet accommodating portion 131 can be pulled out from and accommodated in the apparatus main assembly 101.

Further, on the front side of the image forming apparatus 100, a collecting door 10 as a door member openable for exposing a collecting container 128 to an outside of the image forming apparatus 100 is provided. The collecting door 10 can be openable by being rotated from above toward below about the rotational axis substantially parallel to the horizontal direction and can be closed by being rotated from below toward above about the rotational axis (part (a) of FIG. 5). By opening the collecting portion 10, the collecting container 128 can be mounted into and demounted from the apparatus main assembly 101 by being inserted into and pulled out from the apparatus main assembly 101 (part (b) of FIG. 5).

### 4. Projector Unit

Next, a projecting means for projecting the operation guidance (guidance display, guiding display) will be described. Part (b) of FIG. 4 is a sectional view of the image forming apparatus 100, as seen from the right side, in a state in which the front door 3 is open. Part (b) of FIG. 4 is a top plan view of the discharge tray 111 of the image forming apparatus 100 in a state in which the front door 3 is opened and the toner cartridge 127 is pulled out. Part (c) of FIG. 4 is a top plan view of the discharge tray 111 of the image forming apparatus in a state in which the front door 3 is opened and the drum unit 201 (or the developing unit 202) is pulled out. Part (a) of FIG. 5 is a perspective view of the image forming apparatus 100 in a state in which the collecting door 10 is opened and the uppermost sheet accommodating portion 131 is pulled out. Part (b) of FIG. 5 is a top plan view of the discharge tray 111 of the image forming apparatus 100 in a state in which the collecting door 10 is opened and the collecting container 128 is pulled out and in which the uppermost sheet accommodating portion 131 is pulled out.

In this embodiment, when a side-surface side where the operation portion 2 is disposed is the front(-surface) side, the image forming apparatus 100 includes a projector unit 1 as the projecting means for projecting operation guidance onto a plurality of projection objects provided in the front side. The projector unit 1 projects the operation guidance from a projecting portion (projection opening) provided in the front side and above the plurality of the projection objects onto the projection objects provided in the front side. This projecting portion is disposed so that the projecting portion can project the operation guidance onto the plurality of the projection objects simultaneously. Incidentally, the projector unit 1 may only be required that the projector unit 1 can simultaneously project the operation guidance from above onto the plurality of the projection objects disposed in the front side of the image forming apparatus 100, and may actually project the operation guidance on the projection objects simultaneously or may individually (selectively) project the operation guidance onto the projection objects. Incidentally, the projection from above is not limited to projection from above toward below in the vertical direction, but may also include projection from above toward below with an angle with respect to the vertical direction. For example, in the case where the image forming apparatus 100 is seen from the front side, the projection may also be carried out from the upper left toward the lower right or from the upper right toward the lower left, and in the case where the image forming apparatus 100 is seen from the right side, the projection may also be carried out from the upper rear toward the lower front or from the upper front toward the lower rear. Further, the operation guidance may also be in any form such as illumination, characters, symbols, figures (diagrams), still images (pictures) or moving images (animation), for instructing or illustrating an operating portion, an operating direction, an operating method or the like.

As shown in part (a) of FIG. 4, in this embodiment, the projector unit 1 is provided on the side surface of the image forming apparatus 100 in the front side, particularly on the side surface of the image reading portion 105 in the front side. In this embodiment, the projector unit 1 is projected so that at least a part thereof projects from the side surface in the front side of the image reading portion 105 toward the front side. The projector unit 1 is constituted by a projector 11, a reflection mirror 12 and a projector cover 13 for accommodating these members and is provided with the projection opening 14, as the projecting portion, formed at a lower portion of the projector cover 13. In this embodiment, in the case where the image forming apparatus 100 is seen from the front side, the projection opening 14 is provided in the left side more than the central portion with respect to the left-right direction. Further, in this embodiment, light projected frontward by the projector 11 is reflected by the reflection mirror 12, so that the light is projected downward through the projection opening 14. That is, the projection opening 14 is positioned in the front side more than the plurality of projection objects which are disposed in a projectable region A and onto which the operation guidance is projectable simultaneously, so that it becomes possible to simultaneously project the operation guidance onto the plurality of projection objects.

Thus, in this embodiment, the projector unit 1 is configured to project the light toward the portions positioned below the operation portion 2, and the projection opening 14 is disposed at a substantially same height as the operation portion 2. Here, the substantially same height of the projection opening 14 and the operation portion 2 is not limited to a completely same height, but would be considered that for example, in the case where a casing portion where the projection opening 14 is formed and at least a part of a casing portion of the operation portion 2 overlap with each other with respect to the up-down direction, these portions are at the substantially same height. In this embodiment, a projection axis (optical axis of a projection image projected through the projection opening 14) of the projector unit 1 extends below substantially in the vertical direction. Here, “extends below substantially in the vertical direction” includes not only the case where the optical axis extends below completely in the vertical direction but also the case where the optical axis extends in a direction deviated from vertically below within a range of an error (for example, ±about 10 degrees).

As shown in part (a) of FIG. 3, in a state in which the front door 3 and the collecting door 10 are closed and the sheet accommodating portions 131 are accommodated, the operation guidance can be projected simultaneously onto projection objects including an outside surface of the front door 3, the front door grip 4, the accommodating portion outside surface 5, the accommodating portion grip 6, an outside surface of the collecting door 10, and a floor surface F on which the image forming apparatus 100 is installed. Incidentally, as regards the four accommodating portion outside surfaces 5, the operation guidance can be projected simultaneously onto all of the outside surfaces 5. That is, in the case where the operation guidance is projected simultaneously onto arbitrary two projection objects, a positional (arrangement) relationship between the portion 1 and the projection objects such that an entirety of one projection object is not hidden by a shadow of the other projection object. In the state of part (a) of FIG. 3, in order to guide that which portion should be opened for a necessary operation, by the operator, such as an exchange of consumables or replenishment of the sheets, it is effective that the operation guidance can be projected simultaneously onto the above-described projection objects.

In a state in which the front door 3 is open as shown in part (a) of FIG. 4, the operation guidance can be simultaneously projected onto the cartridge grips 7, the small doors 8 and the screen 9 provided inside the front door 3. Incidentally, as regards the four cartridge grips 7 and the four small doors 8, it is possible to simultaneously project the operation guidance onto all of these members. Further, the screen 9 may also be an inside surface itself of the front door 3 or a member mounted on the inside door of the front door 3. Also in this case, when the operation guidance is projected simultaneously onto arbitrary two projection objects, the projector unit 1 and the projection objects provide a positional relationship such that an entirety of one projection object is not hidden by a shadow of the other projection object. For example, as shown in part (a) of FIG. 4, all of the small doors 8 disposed below the cartridge grips 7 are configured so as not to be hidden by a shadow K of the cartridge grips 7. Further, for example, as shown in part (b) of FIG. 4, even in the case where the toner cartridge 127 is pulled out, most of the screen 9, with respect to the left-right direction, disposed below the toner cartridge 127 is configured so as not to be hidden by the shadow of the toner cartridge 127. Similarly, for example, as shown in part (b) of FIG. 4, even in the case where the small door 8 is opened and the drum unit 201 (or the developing unit 202) is pulled out, most of the screen 9, with respect to the left-right direction, disposed below the unit is configured so as not to be hidden by the shadow of the unit. In the states of parts (a) to (c) of FIG. 4, for example, in order to not only guide the toner cartridge 127 to be exchanged and the small door 8 to be opened but also display explanation of an operation procedure on the screen 9, it is effective that the operation guidance can be projected simultaneously onto the above-described projection objects.

As shown in part (a) of FIG. 5, in a state in which the collecting door 10 is opened and the uppermost sheet accommodating portion 131 is pulled out, the operation guidance can be projected simultaneously onto the inside surface of the collecting door 10 and an inside of the sheet accommodating portion 131 (or the sheet S accommodated in the sheet accommodating portion 131). Further, as shown in part (b) of FIG. 5, in a state in which the collecting door 10 is opened and the collecting container 128 and the uppermost sheet accommodating portion 131 are pulled out, the operation guidance can be projected simultaneously onto an upper surface of the collecting container 128 and an inside of the sheet accommodating portion 131 (or the sheet S accommodated in the sheet accommodating portion 131). Also in these cases, when the operation guidance is projected simultaneously onto the two projection objects, a positional relationship between the projector unit 1 and the projection objects such that an entirety of one projection object is not hidden by the shadow of the other projection object is established.

As described above, according to this embodiment, the projector unit 1 is disposed in the front side of the image forming apparatus 100 and above the projection objects. Further, the projector unit 1 is constituted so as to be capable of simultaneously projecting the operation guidance onto the plurality of projection objects disposed in the front side of the image forming apparatus 100. Specifically, the projection opening 14 of the projector unit 1 is disposed at a position where of the plurality of projection objects onto which the operation guidance is capable of being projected simultaneously, by a shadow of one projection object, other projection objects are not completely hidden. Further, also with respect to the left-right direction in the case where the image forming apparatus 100 is seen from the front side, the projection opening 14 of the projector unit 1 is disposed at the position where of the plurality of projection objects onto which the operation guidance is capable of being projected simultaneously, by the shadow of one projection portion, other projection objects are not completely hidden.

As a result, according to this embodiment, with a simple constitution, the operation guidance can be properly projected onto the plurality of projection objects. That is, according to this embodiment, by projecting the operation guidance from above toward below in the front side of the image forming apparatus 100, the light to be projected onto the plurality of projection objects can be projected onto the plurality of projection objects without being blocked by another projection object or the operator. Further, according to this embodiment, by projecting the operation guidance from above toward below in the front side of the image forming apparatus 100, there is no need to provide the means for changing the direction of the projecting means and to provide the means for adjusting the magnification. As a result, according to this embodiment, in a small and simple constitution, the operation guidance can be projected without blocking the image to be projected and without forming a fluid spot of the projecting means itself.

### Embodiment 2

Another embodiment of the present invention will be described. A basic structure and basic operation of an image forming apparatus in this embodiment are the same as those of the image forming apparatus in Embodiment 1. Accordingly, in the image forming apparatus in this embodiment, elements having the same or corresponding functions or structures as those of the image forming apparatus in Embodiment 1 are represented by the same reference numerals or symbols as in Embodiment 1 and will be omitted from detailed description.

Part (a) of FIG. 6 is a perspective view of an image forming apparatus 100 in this embodiment. Part (b) of FIG. 6 is a partial perspective side view of the image forming apparatus 100 in this embodiment as seen from the right side and shows a state in which a front door 3 is open.

In this embodiment, the projector unit 1 is provided at a lower portion of an operation portion 2 of the image forming apparatus 100 in the front side. In this embodiment, a projector 11 is accommodated inside a device of an apparatus main assembly 101 positioned below the operation portion 2, and a reflection mirror 12 is accommodated at a lower portion of the cover of the operation portion 2, and a projection opening 14 is formed at the lower portion of the cover of the operation portion 2. In this embodiment, in the case where the image forming apparatus 100 is seen from the front side, the projection opening 14 is provided in the right side than the central portion with respect to the left-right direction. In this embodiment, light projected upward by the projector 11 is reflected by the reflection mirror 12, so that the light is projected downward through the projection opening 14. As a result, also in this embodiment, the projector unit 1 is capable of simultaneously projecting the operation guidance from above onto a plurality of projection objects provided in the front side of the image forming apparatus 100.

In this embodiment, in the case where the image forming apparatus 100 is seen from the front side, the projection opening 14 is disposed in the right side than a discharge tray 111. For that reason, in this embodiment, viewability of the sheet S discharged on the discharge tray 111 when the operation guidance is projected by the projector 11 is better than that in Embodiment 1.

### Embodiment 3

Another embodiment of the present invention will be described. A basic structure and a basic operation of an image forming apparatus in this embodiment are the same as those of the image forming apparatuses in Embodiments 1 and 2. Accordingly, in the image forming apparatus in this embodiment, elements having the same or corresponding functions or structures as those of the image forming apparatuses in Embodiments 1 and 2 are represented by the same reference numerals or symbols as in Embodiment 1 and will be omitted from detailed description.

Part (a) of FIG. 7 is a front view of an image forming apparatus 100 in this embodiment. Part (b) of FIG. 7 is a right side view of the image forming apparatus 100 in this embodiment and shows a state in which a sheet accommodating portion 131 is pulled out.

In this embodiment, a projector unit 1 is provided at an end portion of a discharge tray 111 in the front side. In this embodiment, a projector 11 and a reflection mirror 12 are accommodated in a projector cover 13 which has an upper surface constituting a part of the discharge tray 111 and which is provided in the front side of the discharge tray 111, and the projector cover 13 is provided with a projection opening 14. In this embodiment, the projection opening 14 is provided at a substantially central portion with respect to the left-right direction in the case where the image forming apparatus 100 is seen from the front side. In this embodiment, by reflecting light, projected frontward from the projector 11, by the reflection mirror 12, the light is projected downward through the projection opening 14. As a result, also in this embodiment, the projector unit 1 is capable of simultaneously projecting the operation guidance from above onto a plurality of projection objects provided in the front side of the image forming apparatus 100.

Thus, in this embodiment, the projector unit 1 is configured to project the light toward the portions positioned below the discharge tray 111, and the projection opening 14 is disposed at a substantially same height as the discharge tray 111. Here, the substantially same height of the projection opening 14 and the discharge tray 111 is not limited to a completely same height, but would be considered that for example, in the case where a casing portion where the projection opening 14 is formed and at least a part of the discharge tray 111 overlap with each other with respect to the up-down direction, these portions are at the substantially same height.

In this embodiment, as shown in part (b) of FIG. 7, also in the case where the operator carries out an operation in a sitting state, the projection opening 14 of the projector unit 1 is below eyes of the operator. For that reason, in this embodiment, the operator in the sitting state is not readily dazzled by the light from the projector unit 1 compared with the cases of Embodiments 1 and 2.

As described up to now, in the above-described embodiments, as the projection objects provided in the front side of the image forming apparatus, the following members were described as an example. The outside portions (the outer surfaces and grips of the front door 3, the small door 8 and the collecting door 10) of the door members openable toward the front side of the image forming apparatus, the inside portions (the inner surfaces and screens of the front door 3 and the collecting door 10) of the door members, the outside portions (the outer surfaces and grips of the sheet accommodating portions 131) of the accommodating members capable of being pulled out toward the front side of the image forming apparatus, the inside portions of the accommodating members (the sheet accommodating portions 131) in a pulled-out state, the accommodated members (the sheets S accommodated in the sheet accommodating portions 131) of the accommodating members in the pulled-out state, the consumables (the toner cartridges 127 and the cartridge grips 7) detachably mountable to the image forming apparatus in a state in which the door member is open, the portions-to-be-operated (the small doors 8) operated for mounting and demounting the consumables in the state in which the door member is open, and the floor surface F in the front side of the image forming apparatus are usable. In addition to these members, for example, it is possible to cite the following members including the consumables (the drum units 201, the developing units 202, the collecting container 128) detachably mountable to the image forming apparatus in the state in which the door member is open, the sheet feeding portions (the sheet feeding path, the feeding members and the like) in the state in which the door member is open, the portions-to-be-operated (the levers, the knobs and the like for moving, the sheet projecting path or moving (rotating) the feeding member to be operated for removing the sheet from the sheet feeding path, and the sheet (the recording sheet caused a jam) positioned at the sheet feeding portion in the state in which the door member is open. Incidentally, each of the plurality of projection objects onto which the operation guidance can be projected simultaneously may be independently one of the above-described members or portions.

### Embodiment 4

In Embodiments 1 to 3, the constitutions in which the operation guidance was projected onto the projection objects provided in the front side of the image forming apparatus were described. In the following embodiments, a constitution in which the operation guidance is projected onto projection objects provided in a side-surface side of the image forming apparatus will be described. In the image forming apparatus in this embodiment, elements having the same or corresponding functions or structures as those of the image forming apparatuses in Embodiments 1 to 3 are represented by the same reference numerals or symbols and will be omitted from detailed description.

### 1. Structure of Side Surface of Image Forming Apparatus

FIG. 8 is a perspective view of an image forming apparatus 100 in this embodiment, in which a part of each of a front(-side) surface, a right-side surface and an upper surface of the image forming apparatus 100 is shown. FIG. 9 is a perspective view of the image forming apparatus 100, in which the part of each of the front surface, the right-side surface and the upper surface of the image forming apparatus in a state in which a manual feeding tray 141 is open. FIG. 10 is a schematic sectional view of a part of the image forming apparatus 100 in a state in which a right(-hand) door 116 described later is open. Incidentally, in this embodiment, in a state in which the openable front door 3 is closed and a pullable accommodating member is accommodated, in the case where the image forming apparatus 100 is seen from above, the image forming apparatus 100 has a substantially rectangular shape such that a front side surface and a rear side surface are substantially parallel to each other and that a left side surface and a right side surface are substantially parallel to each other.

In this embodiment, the image forming apparatus 100 includes, on the front side surface, specifically on the front side surface of the image reading portion 105, the operating portion 2 for permitting input of various settings such as a process condition of the sheet S, a start instruction of the image forming operation, and the like to the controller C. In this embodiment, the operating portion 2 is provided so as to project from the front side surface of the image reading portion 105 toward the front side. Further, in this embodiment, when the image forming apparatus 100 is seen from the front side, the operation portion 2 is provided in a right side more than a central portion with respect to a left-right direction.

The operating portion 2 is constituted by buttons (switches) 21 as input means for permitting input of instructions to the controller C, a display (liquid crystal screen) 22 as a display means for displaying information for an operator such as a user or a maintenance person. In this embodiment, the display 22 is constituted by a touch panel and also has a function of an input means. The operator operates, in general, the operating portion 2 from the front side of the image forming apparatus 100, so that the operator can input necessary items to the controller C and can cause the image forming apparatus 100 to start the image forming operation.

Further, the image forming apparatus 100 is configured so that the operator can perform maintenance (exchange) from the front side of the image forming apparatus 100 where the operator portion 2, provided outside the image forming apparatus 100 as described above, for inputting an instruction regarding operation of the image forming portion 102 is provided. That is, on the front side surface of the image forming apparatus 100, gate front door 112 as a door member openable for exposing at least a part of an inside of the apparatus main assembly 101 to the outside of the image forming apparatus 100 is provided. When the front door 112 is opened, end portions of the toner cartridges 127 in the front side and small doors for exposing end portions of the process units 121 in the front side to an outside of the image forming apparatus 100 are exposed to the outside of the image forming apparatus 100. Further, by opening the small door, the drum unit 201 and the developing unit 202 can be mounted into the demounted from the apparatus main assembly 101 by being individually inserted into and pulled out from the apparatus main assembly 101 in the front-rear direction. In the front side of the image forming apparatus 100, an accommodating portion outer surface 131a which is a front side surface of the sheet accommodating portion 131 is provided below the front door 112. In the sheet accommodating portion 131, in a state in which the sheet accommodating portion 131 is pulled out from the apparatus main assembly 101, the sheets S are set (accommodated). Further, on the front side of the image forming apparatus 100, a collecting door 115 as a door member openable for exposing a collecting container 128 to an outside of the image forming apparatus 100 is provided below the front door 112. By opening the collecting door 115, the collecting container 128 can be mounted into and demounted from the apparatus main assembly 101 by being inserted into and pulled out from the apparatus main assembly 101.

On the other hand, on the right side surface of the image forming apparatus 100, a right(-hand) door 116 as an openable door member for exposing at least a part of the inside of the apparatus main assembly 101 to the outside of the image forming apparatus 100 is provided. By opening the right door 116, it is possible to perform clearance of a jam (i.e., removal of the jammed sheet S) when the jam guidance in a sheet feeding path 171. As shown in FIG. 10, the right door 116 is connected rotatably with the apparatus main assembly 101 by a hinge provided at a lower end portion thereof. The right door 116 is opened by operation a right door grip 116a so as to be rotated from above toward below about a rotational axis substantially parallel to the horizontal direction as shown in FIG. 8. By opening the right door 116, the sheet S positioned in the sheet feeding path 171 can be removed. The right door 116 is provided with a manual feeding portion 104. As shown in FIG. 9, the manual feeding tray 141 of the manual feeding portion 104 is connected rotatably with the right door 116 by the hinge provided at the lower end portion of the right door 116. As regards the manual feeding tray 141, as shown in FIG. 8, by operation a manual feeding tray grip 141a, the manual feeding tray 141 can be opened by being rotated from above toward below about the rotational axis substantially substantially parallel to the horizontal direction and can be closed by being rotated from below toward above about the rotational axis. On the manual feeding tray 141, in an open state, the sheets S are set (mounted).

### 2. Projector Unit

Next, a projecting means for projecting the operation guidance (guidance display, guiding display) will be described.

In this embodiment, similarly as in Embodiments 1 to 3, when a side-surface side where the operation portion 2 is disposed is the front(-surface) side, the image forming apparatus 100 includes a projector unit 1 as the projecting means for projecting operation guidance onto the projection object provided in a side surface (lateral side) side adjacent to the front side-side surface (front side surface). The projector unit 1 projects the operation guidance from a projecting portion (projection opening 14) provided in the lateral side surface and above the projection object onto the projection object provided in the front side. In this embodiment, the projecting portion is disposed in the rear side than the substantially central portion of a region, where the projection object is disposed, with respect to the depth direction when the image forming apparatus 100 is seen from the front side. Further, in this embodiment, the operation guidance projected onto the project object by the projector unit 1 is operation guidance regarding an operation object provided in the lateral side surface side of the image forming apparatus 100.

Here, the projection from above also includes projection from above toward below in a state in which a projection optical axis (optical axis of a projection image projected from the projecting portion) of the projector unit 1 has an angle with respect to the vertical direction, and in this embodiment, the projection is performed from above-described in the rear side toward below in the front side. In this embodiment, the projecting portion of the projector unit 1 is disposed so as to simultaneously or individually project the operation guidance onto a plurality of projection objects provided in the lateral side surface side of the image forming apparatus 100. Here, the simultaneous projection of the operation guidance onto the plurality of projection objects includes, in addition to the simultaneous projection in actuality, the case where the operation guidance is selectively projected onto either of the plurality of projection objects onto which the operation guidance is capable of being projected. Further, the operation guidance may also be in any form such as illumination, characters, symbols, figures (diagrams), still images (pictures) or moving images (animation), for instructing or illustrating an operating portion, an operating direction, an operating method or the like. This will be specifically described below.

As shown in FIGS. 8 and 9 in this embodiment, the projector unit 1 is provided on the right side surface of the image forming apparatus 100, specifically on the right side surface of the image reading portion 105 and on the right side surface of the apparatus main assembly 101 in the rear side than the right door 116. The projector unit 1 is constituted by a projector 11, a reflection mirror 12 and a projector cover 13 for accommodating these members and is provided with the projection opening 14, as the projecting portion, formed as a part of the projector cover 13. The projection opening 14 is disposed above the plurality of projection objects in a projectable range (A in FIGS. 8 and 9) and in the rear side, with respect to the depth direction when the image forming apparatus 100 is seen from the front side, than the substantially central position (B of FIG. 8) in a region where the plurality objects are disposed. That is, with respect to the depth direction when the image forming apparatus 100 is seen from the front side, the projection opening 14 is disposed at a position remoter from the operator standing in the front side of the image forming apparatus 100 tan the substantially central position B of the region where the projection objects in the right surface side of the image forming apparatus 100 are disposed. Further, in this embodiment, as shown in FIG. 10, the projection opening 14 is disposed so as to project toward the outside (right side) from the right door 116 in a state in which the right door 116 is closed.

Incidentally, the substantially central position B of the region, where the projection objects are disposed, with respect to the depth direction when the image forming apparatus 100 is seen from the front side refers to a substantially central position between a frontmost position and a rearmost position of the projection objects disposed in the lateral side surface side of the image forming apparatus 100. In this embodiment, the substantially central position corresponds to a substantially central position between a front side end portion and a rear side end portion of the right door 116, largest in width with respect to the depth direction, of the projection objects disposed in the right side (surface side) of the image forming apparatus 100. In this embodiment, feeding of the sheet S by the sheet feeding portion 107 and the manual feeding portion 104 is carried out on a center line basis with respect to a direction substantially perpendicular to a feeding direction of the sheet S. For that reason, in this embodiment, the substantially central position of the region, where the projection objects are disposed, with respect to the depth direction when the image forming apparatus 100 is seen from the front side corresponds to a substantially central portion with respect to the direction substantially perpendicular to the feeding direction of the sheet S when the image forming apparatus 100 is seen from the front side. Further, in this embodiment, the right door 116 is disposed at a central portion with respect to the depth direction when the image forming apparatus 100 is seen from the front side. For that reason, in this embodiment, the substantially central position of the region, where the projection objects are disposed, with respect to the depth direction when the image forming apparatus 100 is seen from the front side corresponds to a substantially central position of the image forming apparatus 100 with respect to the depth direction of the image forming apparatus 100. Light projected upward and frontward by the projector 11 is reflected by the reflection mirror 12, so that the portion 1 projects the light downward and frontward through the projection opening 14. As a result, the projector unit 1 is capable of projecting the operation guidance simultaneously or individually onto the projection objects disposed in a projectable region A. Particularly, in this embodiment, the projector unit 1 is configured to project the light toward the portions positioned below the operation portion 2, and the projection opening 14 is disposed at a substantially same height as the operation portion 2. Here, the substantially same height of the projection opening 14 and the operation portion 2 is not limited to a completely same height, but would be considered that for example, in the case where a casing portion where the projection opening 14 is formed and at least a part of a casing portion of the operation portion 2 are in positions where these portions overlap with each other with respect to the up-down direction, these portions are at the substantially same height. Further, in this embodiment, the projection opening 14 is disposed above a registration roller 172, provided in the apparatus main assembly 101 for controlling at least one of feeding timing and feeding attitude of the sheet S supplied to the image forming portion 102.

As shown in FIG. 8, in a state in which the manual feeding tray 141 and the right door 116 are closed. The projector unit 1 is capable of projecting the operation guidance onto the following projection objects, such as an outside surface of the manual feeding tray 141, the manual feeding tray grip 141a operated when the manual feeding tray 14 is opened, an outside surface of the right door 116 and a right door grip 116a operated when the right door 116 is opened.

As shown in FIG. 9, in a state in which the manual feeding tray 141 is open, the projector unit 1 is capable of projecting the operation guidance onto the following projection objects, such as an inside surface (sheet stacking surface) 141b of the manual feeding tray 141 and the sheet(s) S stacked on the manual feeding tray 141.

As shown in FIG. 10, in a state in which the right door 116 is open, the projector unit 1 is capable of projecting the operation guidance onto the following projection objects, such as the sheet feeding portion 107 and the sheet S stagnating on the sheet feeding portion 107, which are exposed by opening the right door 116.

As shown in FIG. 8, in the state in which the manual feeding tray 141 and the right door 116 are closed, by the instruction of the controller C, the projector unit 1 is capable of projecting the following operation guidance. For example, in the case where a jam at the sheet feeding portion 107 is detected or in the like case, in order to guide an opening operation of the right door 116, it is possible to illuminate the outside surface of the right door 116 and the right door grip 116a with light. Further, an instruction such as an operation procedure may also be displayed on the outside surface of the right door 116. Further, for example, in the case where feeding of the sheet S from the manual feeding tray 114 is selected at the operation portion 2 or in the like case, in order to guide an opening operation of the manual feeding tray 141, it is possible to illuminate the outside surface of the manual feeding tray 141 and the manual feeding tray grip 141a with light. Further, an instruction such as an operation procedure may also be displayed on the outside surface of the manual feeding tray 114.

As shown in FIG. 9, in the state in which the manual feeding tray 141 is open, by the instruction of the controller C, the projector unit 1 is capable of projecting the following operation guidance. In the state in which the manual feeding tray 141 is opened, the sheet stacking (mounting) surface 141b on which the sheet S is stacked (mounted) is exposed. For that reason, in this embodiment, information (image formation information) D such as a size of the sheet S fed from the manual feeding tray 141 is projected onto the sheet stacking surface 141b. The operator can properly set a sheet side surface regulating member 141c which is an operation object while seeing the image formation information D directly displayed on the sheet stacking surface 141b itself which is the projection object. An instruction of an operation procedure such as an operation direction may also be displayed on the sheet side surface regulating member 141c or in the neighborhood thereof.

As shown in FIG. 10, in the state in which the right door 116 is opened, by the instruction of the controller C, the projector unit 1 is capable of projecting the following operation guidance. In the state in which the right door 116 is opened, at least a part of the inside of the apparatus main assembly 101, i.e., a part of the sheet feeding portion 107 in this embodiment, is exposed. For that reason, in this embodiment, onto the sheet feeding portion 107 or the sheet S as the operation object positioned at the sheet projecting portion 107, operation guidance as to jam clearance (removal of the jammed sheet S) is projected. In this embodiment, the projectable range A is set so as to include the sheet stacking surface 141b of the manual feeding tray 141 as described above, and also includes a part of the sheet feeding portion inside the apparatus main assembly 101 and the inside surface of the opened right door 116, and the like.

FIG. 11 is a perspective view showing a part of the right side surface of the image forming apparatus 100 in the state in which the right door 116 (not shown in FIG. 11) is open. The sheet feeding portion 107 exposed by opening the right door 116 includes the registration roller 172, a feeding guide 171 constituting the sheet feeding portion 107 in a side upstream of the registration roller 172, and a pre-registration roller 173 in a side upstream of the feeding guide 171. Further, the sheet feeding portion 107 includes a first sheet sensor 3 and a second sheet sensor 4 which are sheet detecting means for detecting the presence or absence of the sheet S. The first sheet sensor 3 is provided on the feeding guide 171, and the second sheet sensor 4 is provided in a side upstream of the pre-registration roller 173. “Upstream” and “downstream” as regards the sheet feeding portion 107 refer to those with respect to a normal feeding direction of the sheet S during image formation.

Parts (a) and (b) of FIG. 13 are sectional views of a neighborhood of the first sheet sensor 3. In this embodiment, the first sheet sensor 3 includes a photo-sensor 31 and a sheet detecting member 32. The sheet detecting member 32 includes a free end portion 32a contactable with the sheet S, an abutting door 32b and an arcuate portion 32c, and is urged by a torsion coil spring 33 so as to be rotated in the clockwise direction in the figure. As shown in part (a) of FIG. 13, when there is no sheet S, the sheet detecting member 32 is in a position where the abutting portion 32b is abutted by the torsion coil spring 33 against an abutment surface 171a provided on the feeding guide 171. In this state, light emitted from a light-emitting portion of the photo-sensor 31 is detected by a light-receiving portion of the photo-sensor 31 without being blocked by the arcuate portion 32c. The first sheet sensor 3 detects that there is no sheet S in this state. On the other hand, as shown in part (b) of FIG. 13, when the sheet S passes through the first sheet sensor 3, the free end portion 32a is pushed up by the sheet S. In this state, the arcuate portion 32b blocks the light between the light-emitting portion and the light-receiving portion of the photo-sensor 31. The first sheet sensor 3 detects that in this state, the sheet S is in a present (existing) state. After the sheet S passed through the first sheet sensor 3, the sheet detecting member 32 is returned to a predetermined position shown in part (a) of FIG. 13 by the torsion coil spring 33. In this embodiment, also the second sheet sensor 4 has the same constitution as the above-described first sheet sensor 3.

Parts (a) and (b) of FIG. 12 are perspective views, of a part of the image forming apparatus 100 at the right side surface thereof, showing an example of operation guidance displayed in the state in which the right door 116 is opened. Part (a) of FIG. 12 shows, as an example of a state of the sheet S during the jam clearance, a state in which the sheet S reaches the pre-registration roller 173 but does not reach the first sheet sensor 3. In this state, the controller C provides an instruction on the basis of detection results of the first and second sheet sensors 3 and 4, so that the projector unit 1 is capable of projecting operation guidance, such as an upward arrow E showing, e.g., a removing direction of the sheet S, onto the surface of the feeding guide 171 and a leading end portion of the sheet S. On the other hand, Part (b) of FIG. 12 shows, as another example of a state of the sheet S during the jam clearance, a state in which the sheet S reaches a position (secondary transfer opposite roller 213) corresponding to a secondary transfer portion and exists on the first sheet sensor 3. In this state, the controller C provides an instruction on the basis of detection results of the first and second sheet sensors 3 and 4, so that the projector unit 1 is capable of projecting operation guidance, such as a downward arrow E showing, e.g., a removing direction of the sheet S, onto a trailing end portion of the sheet S. positioned on the feeding guide 171.

Incidentally, the above-described arrows E may also be animation images in which a part thereof strongly shines, and the strongly shining portion moves step by step (for example, the strongly shining portion moves from a base end toward a top end).

As described above, in this embodiment, the projection opening 14 of the projector unit 1 is disposed above the projection objects and in the rear side (remote side from the front side surface) than the substantially central position B of the region, where the projection objects are disposed, with respect to the depth direction when the image forming apparatus 100 is seen from the front side. At this time, the projection opening 14 can be disposed in the front side in a range in which the eye can reach the projection objects (such as the sheet S on the manual feeding tray 141 and the sheet feeding portion 107 in the state in which the right door 116 is open) when the projection objects are seen from the operator standing in the front side of the image forming apparatus 100.

Thus, in this embodiment, by projecting the operation guidance downward and toward the front surface direction through the projection opening 14, without providing a constitution for changing a direction of the projecting means, the operation guidance can be projected onto the projection objects in the right side of the image forming apparatus 100 with a relatively small and simple constitution. Further, by employing such a projection direction, it is possible to suppress blocking, by the operator, of the light projected through the projection opening 14, and it is also possible to suppress formation of the blind spot by the projector unit 1 itself. That is, according to this embodiment, even when the operator performs the operation of the right-side operation object from the front side of the image forming apparatus 100, it is possible to suppress the blocking, by the operator, of the operation guidance projected by the projector unit 1. Further, according to this embodiment, even when the projector unit 1 is projected toward the outside of the right side surface of the image forming apparatus 100, it is possible to suppress the formation of the blind spot by the projector unit 1 itself.

### Embodiment 5

Another embodiment of the present invention will be described. A basic structure and basic operation of an image forming apparatus in this embodiment are the same as those of the image forming apparatuses in Embodiments 1 to 4. Accordingly, in the image forming apparatus in this embodiment, elements having the same or corresponding functions or structures as those of the image forming apparatuses in Embodiments 1 to 4 are represented by the same reference numerals or symbols as in Embodiments 1 to 4 and will be omitted from detailed description.

Part (a) of FIG. 14 is a perspective view showing a part of each of the front side surface, the right side surface and the upper surface of the image forming apparatus 100 in this embodiment in a state in which the manual feeding tray 141 is open. Part (b) of FIG. 14 is a perspective view showing a part of the right side surface of the image forming apparatus 100 in this embodiment in a state in which the right door 116 is open. From part (b) of FIG. 14, illustration of the right door 116 is omitted.

In this embodiment, the projector unit 1 is provided on the right side surface of the image forming apparatus 100, specifically, on the right side surface of the apparatus main assembly 101 in the rear side than the right door 116. Further, in this embodiment, the projection opening 14 of the projector unit 1 is provided at a position lower than the operation portion 2. Incidentally, also in this embodiment, similarly as in Embodiment 1, the projection opening 14 of the projector unit 1 is disposed above the registration roller 172.

In this embodiment, the projection objects of the projector unit 1 are the sheet stacking surface 141b of the manual feeding tray 141 shown in part (a) of FIG. 14, and a part of the sheet feeding portion 107 in a side upstream of the registration roller 172 shown in part (b) of FIG. 14.

The operation guidance projected onto the sheet stacking surface 141b of the manual feeding tray 141 and the sheet feeding portion 107 positioned in the side upstream of the registration roller 172 can be constituted similarly as in Embodiment 1. In part (b) of FIG. 14, an example of the case where the upward arrow E showing the removing direction of the sheet S is projected onto the leading end portion of the sheet S and the feeding guide 171.

In this embodiment, the projection objects of the projector unit 1 are smaller in number than Embodiment 1, and the projectable range A is narrower than Embodiment 1. However, in this embodiment, a distance between the projector unit 1 and the projection objects is small (close), and therefore, illuminance required for the projector unit 1 may also be small, so that the projector unit 1 can be downsized. The projectable range A of the projector unit 1 can be appropriately set. In the case where the projectable range A is relatively narrow as in this embodiment, for example, the projectable range A may also be a range in the rear side than a substantially central position B in a region, where the projection objects are disposed, with respect to the depth direction when the image forming apparatus 100 is seen from the front side.

### Embodiment 6

Another embodiment of the present invention will be described. In the image forming apparatus in this embodiment, elements having the same or corresponding functions or structures as those of the image forming apparatuses in Embodiments 1 to 5 are represented by the same reference numerals or symbols as in Embodiment 1 and will be omitted from detailed description.

Part (a) of FIG. 15 is a top plan view of an image forming apparatus 100 in this embodiment. Parts (b) and (c) of FIG. 15 are schematic sectional views of the image forming apparatus 100 in this embodiment as seen from the front side, in which part (b) shows a state in which the right door 116 is closed and part (c) shows a state in which the right door 116 is open.

In this embodiment, the projector unit 1 is provided on the right side surface of the image forming apparatus 100, specifically, on the right side surface of the image reading portion 105 (and above the right door 116). Particularly, in this embodiment, the projection opening 14 of the projector unit 1 is provided inside the apparatus main assembly 101 with respect to the outside surface of the right door 116 in the state in which the right door 116 is closed. Further, in this embodiment, similarly as in Embodiment 1, the projection opening 14 of the projector unit 1 is disposed at the substantially same height as the operation portion 2 (and above the registration roller 172).

In this embodiment, the projection objects of the projector unit 1 are the inside surface of the opened right door 116, the sheet feeding portion 107, the sheet S positioned at the sheet feeding portion 107, and the like. Incidentally, in this embodiment, the projector unit 1 is capable of projecting the operation guidance similar to the operation guidance when the right door 116 is opened in Embodiments 1 and 2.

In the case where the projection objects of the projector unit 1 are principally the inside of the right door 116 and the apparatus main assembly 101, the projection opening 14 of the projector unit 1 can be disposed inside the apparatus main assembly 101 with respect to the outside surface of the right door 116. In this case, an amount in which the projector unit 1 projects from the side surface toward the outside of the image forming apparatus 100 can be reduced. Accordingly, even in the case where the operator opens the right door 116 and operates the operation object positioned in the right side from the front side of the image forming apparatus 100, the blind spot of the operator can be less generated by the projector unit 1.

In this embodiment, as described above, the blind spot by the portion 1 is not readily formed, and therefore, there is a relatively high latitude in arrangement of the projection opening 14 of the projector unit 1 with respect to the depth direction when the image forming apparatus is seen from the front side. However, in order to suppress the blocking, by the operator, of the operation guidance projected from the projector unit 1, the projection opening 14 may preferably be disposed at the substantially central position B or in the rear side than the substantially central position B of the region, where the projection objects are disposed, with respect to the depth direction when the image forming apparatus 100 is seen from the front side. In this embodiment, the projection opening 14 is disposed at the substantially central position B. Also in this embodiment, similarly as Embodiment 1, the substantially central position of the region, where the projection objects are disposed, with respect to the depth direction when the image forming apparatus 100 is seen from the front side corresponds to a substantially central position with respect to the direction substantially perpendicular to the feeding direction of the sheet S when the image forming apparatus 100 is seen from the front side.

As described above, the present invention was explained in accordance with specific embodiments, but is not limited to the above-described embodiments.

The projection objects include those cited in the above-described embodiments and may also be at least one of the following members. It is possible to cite the outside portions (the outside surface and the grip and the like of the right door 116) of the door member openable toward the lateral side surface side of the image forming apparatus, the inside portions (the inside surface and the like of the right door 116) of the door member, the sheet feeding portions (the registration roller 172, the feeding guide 171 and the like) in the state in which the door member is open, the portions-to-be-operated (the levers, the knobs and the like for moving, the sheet projecting path or moving (rotating) the feeding member to be operated for removing the sheet from the sheet feeding path, the sheet (the recording sheet caused the jam) positioned at the sheet feeding portion in the state in which the door member is open, the sheet stacking portion (the manual feeding tray 141 and the like) openable toward the lateral side surface side of the image forming apparatus, the inside surface (the sheet feeding surface 141a and the like of the manual feeding tray 141) of the sheet stacking portion, the sheet (the recording sheet stacked on the manual feeding tray 141) stacked on the sheet stacking portion, the outside portions (the outside surface and the grip and the like of the sheet accommodating portion) of the accommodating member capable of being pulled out toward the lateral side surface side of the image forming apparatus, the inside portion (the inside portion of the sheet accommodating portion) of the accommodating member in the pulled-out state of the accommodating member, the accommodated member (the sheet accommodated in the sheet accommodating portion) accommodated in the accommodating member in the pulled-out state, the consumables (the toner cartridges, the drum units, the developing units, the collecting container, the operation portions such as the grips of these members) detachably mountable to the image forming apparatus in a state in which the door member openable toward the lateral side surface side of the image forming apparatus is opened, the portions-to-be-operated for mounting and demounting the consumables in a state in which the door member is open, and the floor surface in the lateral side surface side of the image forming apparatus.

Further, in the above-described embodiments, the lateral side surface of the image forming apparatus was the right side surface of the image forming apparatus, but may also be the left side surface of the image forming apparatus. Also in the left side surface of the image forming apparatus, the door member for opening the sheet feeding portion in order to enable the jam clearance, and the sheet stacking portion on which the sheet is stacked are provided in some cases.

In the above-described embodiments, the present invention was applied to the color image forming apparatus, including the plurality of the image forming portions, but is also applicable to an image forming apparatus for a single color (for example, black), in which a single image forming portion is provided, so that it is possible to obtain effects similar to those in the above-described embodiments.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Applications Nos. 2016-236256 filed on Dec. 5, 2016 and 2017-053504 filed on Mar. 17, 2017, which are hereby incorporated by reference herein in their entirety.

What is claimed is:

1. An image forming apparatus comprising:
a main assembly including a feeding portion configured to feed a sheet and an image forming portion configured to form an image on the fed sheet;
an openable cover provided on a side surface of said main assembly and openable for exposing a component part in said main assembly by opening a space above the component part with respect to a vertical direction; and
a projecting portion provided above said openable cover with respect to the vertical direction and capable of projecting light toward the component part when said openable cover is opened.

2. An image forming apparatus according to claim 1, wherein said projecting portion is capable of projecting the light toward a plurality of component parts exposed when said openable cover.

3. An image forming apparatus according to claim 1, wherein said openable cover is provided on a front surface of said main assembly.

4. An image forming apparatus according to claim 3, wherein said projecting portion simultaneously projects information on an operation onto the component part and an inner surface of said openable cover which is open.

5. An image forming apparatus according to claim 3, further including an operation portion provided on the front surface of said main assembly and configured to operate said image forming apparatus,
wherein said projecting portion and said operation portion are arranged in a lateral direction.

6. An image forming apparatus according to claim 3, further including an operation portion provided on the front surface of said main assembly and configured to operate said image forming apparatus,
wherein said projecting portion is disposed below said operation portion with respect to the vertical direction.

7. An image forming apparatus according to claim 3, wherein said openable cover is provided in a rear side than said projecting portion with respect to a front-rear direction of said main assembly.

8. An image forming apparatus according to claim 3, wherein the component part is a developer accommodating container accommodating a developer.

9. An image forming apparatus according to claim 3, wherein the component part is an image bearing unit bearing an image bearing member.

10. An image forming apparatus according to claim 1, further comprising an operation portion configured to operate said image forming apparatus,
wherein said operation portion is provided on a front surface of said main assembly and said openable cover is provided on a laterally side surface of said main assembly.

11. An image forming apparatus according to claim 10, wherein said projecting portion is disposed in a rear side than a central portion of the laterally side surface with respect to a front-rear direction of said main assembly.

12. An image forming apparatus according to claim 10, wherein said projecting portion is disposed so as to be substantially flush with said operation portion.

13. An image forming apparatus according to claim 10, wherein said projecting portion is disposed at a position lower than said operation portion.

14. An image forming apparatus according to claim 10, wherein said openable device opens and closes said feeding portion.

15. An image forming apparatus according to claim 10, wherein said projecting portion projects the light onto the component part constituting said feeding portion when said openable cover is open.

16. An image forming apparatus comprising:
a main assembly including an image forming portion configured to form an image on a sheet which is fed;
a sheet accommodating cassette capable of being pulled out from a front surface of said main assembly toward a front side with respect to a front-rear direction of said main assembly and configured to accommodate the sheet; and
a projecting portion provided above said sheet accommodating cassette with respect to a vertical direction and capable of projecting light toward said sheet accommodating cassette.

17. An image forming apparatus according to claim 16, further including an operation portion provided on the front surface of said main assembly and configured to operate said image forming apparatus,
wherein said projecting portion and said operation portion are arranged in a lateral direction.

18. An image forming apparatus according to claim 16, further including an operation portion provided on the front surface of said main assembly and configured to operate said image forming apparatus,
wherein said projecting portion is disposed below said operation portion with respect to the vertical direction.

19. An image forming apparatus according to claim 16, wherein said projecting portion is capable of projecting information on an operation onto an inside of said sheet accommodating cassette which is pulled out.

20. An image forming apparatus comprising:
a main assembly including a feeding portion configured to feed a sheet and an image forming portion configured to form an image on the fed sheet;
an operation portion provided in a front side of said main assembly and configured to operate said image forming apparatus;
a sheet mounting portion which is provided on a side surface of said main assembly, which is openable by being rotated about a rotational axis with respect to a substantially horizontal direction, and which is configured to mount the sheet to be fed to said image forming portion; and
a projecting portion which is provided above, with respect to a vertical direction, said a sheet mounting surface of said sheet mounting portion which is open, which is provided in a rear side of said main assembly more than a central portion of the side surface with respect to the horizontal direction, and which is capable of projecting light toward said sheet mounting portion when said sheet mounting portion is open.

21. An image forming apparatus according to claim 20, wherein said projecting portion projects, onto the sheet mounting surface, information on the sheet mountable on said sheet mounting portion.

22. An image forming apparatus according to claim 20, further comprising an openable cover provided on the side surface and capable of projecting light toward said feeding portion when said openable cover is opened.

23. An image forming apparatus comprising:
a main assembly including a feeding portion configured to feed a sheet and an image forming portion configured to form an image on the fed sheet;
an operation portion provided in a front side of said main assembly and configured to operate said image forming apparatus;
an openable cover provided on a side surface of said main assembly and openable for exposing said feeding portion in said main assembly; and
a projecting portion provided in a rear side of said main assembly move than a central portion of the side surface with respect to a horizontal direction and capable of projecting light toward said projecting portion when said openable cover is opened.

24. An image forming apparatus according to claim 23, wherein said projecting portion is disposed on the side surface so as to be adjacent to said feeding portion, with respect to a vertical direction, to be opened by said openable cover.
